(19) United States
(12) Patent Application Publication
(10) Pub. No.: US 2025/0218849 A1
(43) Pub. Date: Jul. 3, 2025

(54) WAFER BONDING APPARATUS

(71) Applicant: SAMSUNG ELECTRONICS CO., LTD., Suwon-si (KR)

(72) Inventors: Sangjun Park, Suwon-si (KR); Taehong Min, Suwon-si (KR); Jaeho Hong, Suwon-si (KR); Bongcheol Kim, Suwon-si (KR); Sangho Yun, Suwon-si (KR)

(73) Assignee: SAMSUNG ELECTRONICS CO., LTD., Suwon-si (KR)

(21) Appl. No.: 18/812,526

(22) Filed: Aug. 22, 2024

(30) Foreign Application Priority Data
Dec. 27, 2023 (KR) 10-2023-0193485
Mar. 13, 2024 (KR) 10-2024-0034954

(51) Int. Cl. H01L 21/683; H01L 21/67

(52) U.S. Cl. CPC H01L 21/6835; H01L 21/67092; H01L 21/6838; H01L 2221/68318; H01L 2221/68381

(57) ABSTRACT

Provided is a wafer bonding apparatus including a first chuck configured to suction a first wafer on a first surface of the first chuck, a second chuck configured to suction a second wafer on a second surface of the second wafer that faces the first surface of the first chuck, a plurality of bonding pin members in the second chuck in a direction parallel to the second surface of the second chuck, the plurality of bonding pin members being configured to be individually operable, and a plurality of drivers connected to the plurality of bonding pin members, respectively, the plurality of drivers being configured to move the connected plurality of bonding pin members, respectively, in a first direction perpendicular to the second surface of the second chuck, wherein the second chuck includes a plurality of vacuum regions adjacent to the plurality of bonding pin members, respectively.

### CROSS-REFERENCE TO RELATED APPLICATION(S)

This application claims priority to Korean Patent Application Nos. Oct. 10, 2023-0193485 and 10-2024-0034954 filed on Dec. 27, 2023 and Mar. 13, 2024, respectively, in the Korean Intellectual Property Office, the disclosures of which are incorporated herein by reference in their entireties.

### BACKGROUND

### 1. Field

One or more embodiments of the present disclosure relate to a wafer bonding apparatus.

### 2. Description of Related Art

In a semiconductor device manufacturing process, a wafer bonding process, bonding two wafers to each other, may be performed. The wafer bonding process may be performed to improve a packaging density of semiconductor chips in a semiconductor device. The wafer bonding process may be performed in a wafer-to-wafer method, in which two wafers are directly bonded to each other without a separate medium. The wafer-to-wafer method may typically be performed using a wafer bonding apparatus including a bonding chuck on which wafers are disposed and a pressing unit to press the wafers. When these wafers are bonded, deformation may occur in the wafers, and a deformation map may be generated in the pair of wafers after bonding, due to pressing force on the wafers and a gap difference between the wafers. Due to this deformation map, bonding accuracy may deteriorate, and furthermore, defects may occur in subsequent processes after bonding.

### SUMMARY

One or more embodiments provide a wafer bonding apparatus that can improve bonding accuracy by applying pressure to the wafer on a region basis.

One or more embodiments provide a wafer bonding apparatus that can improve an overlay distortion phenomenon in subsequent processes after bonding.

According to an aspect of one or more embodiments, there is provided a wafer bonding apparatus, including a first chuck configured to suction a first wafer on a first surface of the first chuck, a second chuck configured to suction a second wafer on a second surface of the second wafer that faces the first surface of the first chuck, a plurality of bonding pin members in the second chuck in a direction parallel to the second surface of the second chuck, the plurality of bonding pin members being configured to be individually operable, and a plurality of drivers connected to the plurality of bonding pin members, respectively, the plurality of drivers being configured to move the connected plurality of bonding pin members, respectively, in a first direction perpendicular to the second surface of the second chuck, wherein the second chuck includes a plurality of vacuum regions adjacent to the plurality of bonding pin members, respectively.

According to another aspect of one or more embodiments, there is provided a wafer bonding apparatus, including a first chuck configured to suction a first wafer on a first surface of the first chuck, a second chuck configured to suction a second wafer on a second surface of the second chuck that faces the first surface, a plurality of bonding pin members in the second chuck and in a direction parallel to the second surface, the plurality of bonding pin members being configured to be individually operable, and a plurality of drivers connected to the plurality of bonding pin members, respectively, the plurality of drivers being configured to move the connected plurality of bonding pin members, respectively, in a first direction perpendicular to the second surface of the second chuck, wherein the second chuck includes a plurality of vacuum openings adjacent to the plurality of bonding pin members, respectively, and vacuum pressures of the plurality of vacuum openings being configured to be individually adjustable.

According to still another aspect of one or more embodiments, there is provided a wafer boding apparatus, including a chamber portion including a processing space, a first chuck in a first region of the processing space, the first chuck being configured to vacuum-suction a first wafer on a first surface of the first chuck, a second chuck configured to vacuum-suction a second wafer on a second surface of the second chuck facing the first surface, a plurality of bonding pin members in the second chuck in a direction parallel to the second surface, the plurality of bonding pin members being configured to be individually operable, and a plurality of drivers connected to the plurality of bonding pin members, respectively, the plurality of drivers being configured to move the plurality of bonding pin members, respectively, in a first direction perpendicular to the second surface of the second chuck, wherein the second chuck includes a plurality of vacuum regions adjacent to the plurality of bonding pin members, respectively, vacuum pressures of the plurality of vacuum regions being configured to be individually adjusted, and a plurality of vacuum openings being spaced apart from each other in each vacuum region of the plurality of vacuum regions adjacent to the plurality of bonding pin members, respectively.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a diagram illustrating a related wafer bonding apparatus;

FIG. 2 is a diagram illustrating a wafer bonding apparatus according to one or more embodiments

FIG. 3 is a top view illustrating a second chuck, taken along line A-A of FIG. 2;

FIG. 4 is a diagram illustrating a first position state of bonding pin members in a second chuck of a wafer bonding apparatus according to one or more embodiments;

FIG. 5 is a diagram illustrating a second position state of bonding pin members in a second chuck of a wafer bonding apparatus according to one or more embodiments;

FIG. 6 is a diagram illustrating a third position state of bonding pin members in a second chuck of a wafer bonding apparatus according to one or more embodiments;

FIG. 7 is a diagram illustrating a fourth position state of bonding pin members in a second chuck of a wafer bonding apparatus according to one or more embodiments;

FIG. 8 is a diagram illustrating a fifth position state of bonding pin members in a second chuck of a wafer bonding apparatus according to one or more embodiments; and

FIG. 9 is a diagram illustrating a wafer bonding apparatus according to one or more other embodiments.

### DETAILED DESCRIPTION

Hereinafter, embodiments will be described with reference to the accompanying drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

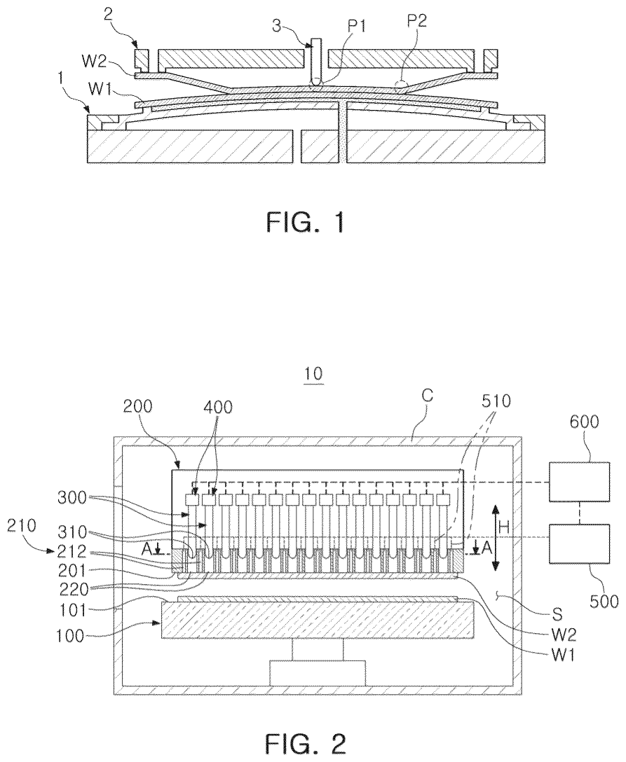

FIG. 1 is a diagram showing a related wafer bonding apparatus.

As shown in FIG. 1, the related wafer bonding apparatus may include a first chuck 1 configured to support a first wafer W1 and a second chuck 2 positioned above the first chuck 1 and configured to support a second wafer W2, the first chuck 1 and the second chuck 2 being disposed in a chamber. A pressing pin 3 configured to move up and down is disposed in a center portion of the second chuck 2 to press a center portion of the second wafer W2. In this wafer bonding apparatus, when bonding the first wafer W1 and the second wafer W2, when the pressing pin 3 presses the second wafer W2 while an edge portion of the second wafer W2 is suctioned and supported by the second chuck 2, a shape of the second wafer W2 will be deformed. At this time, an inflection point PI may occur at the center portion of the second wafer W2 due to the pressure caused by the pressing pin 3. In addition, the second chuck 2 releases the edge portion of the second wafer W2 to complete the bonding of the second wafer W2 and the first wafer W1. In this case, an inflection point P2 may occur due to excessive deformation in a middle region between the central portion and the edge portion of the second wafer W2. These inflection points Pl and P2 may be a major cause of defects in subsequent processes, such as overlay distortion in the overlay process after completing the bonding of the first wafer W1 and the second wafer W2.

In order to solve these problems, the wafer bonding apparatus according to one or more embodiments may press the wafer on a region basis, as will be described below with reference to the drawings.

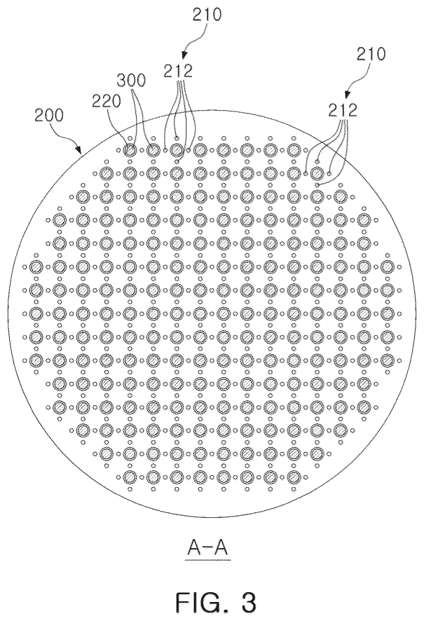

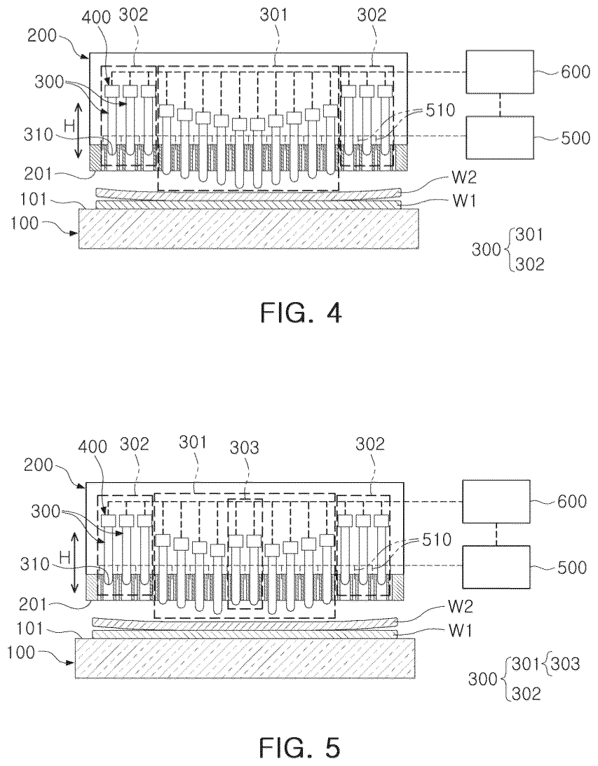

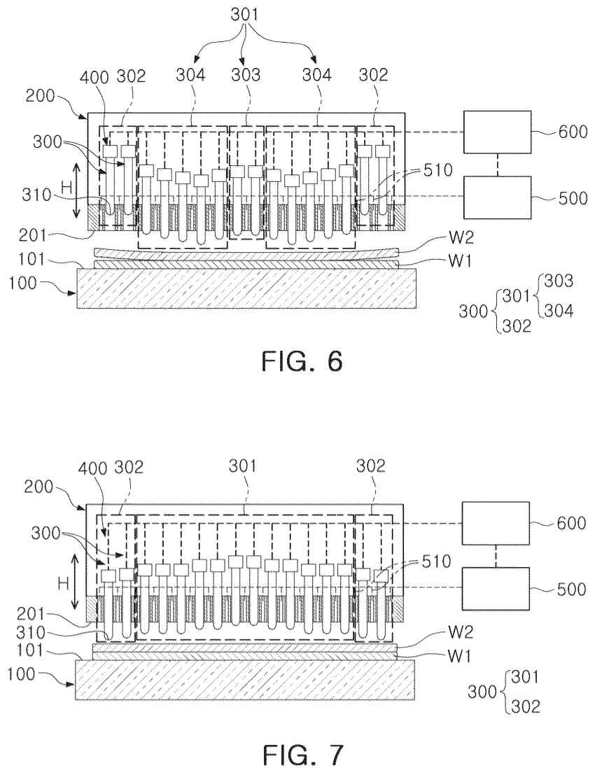

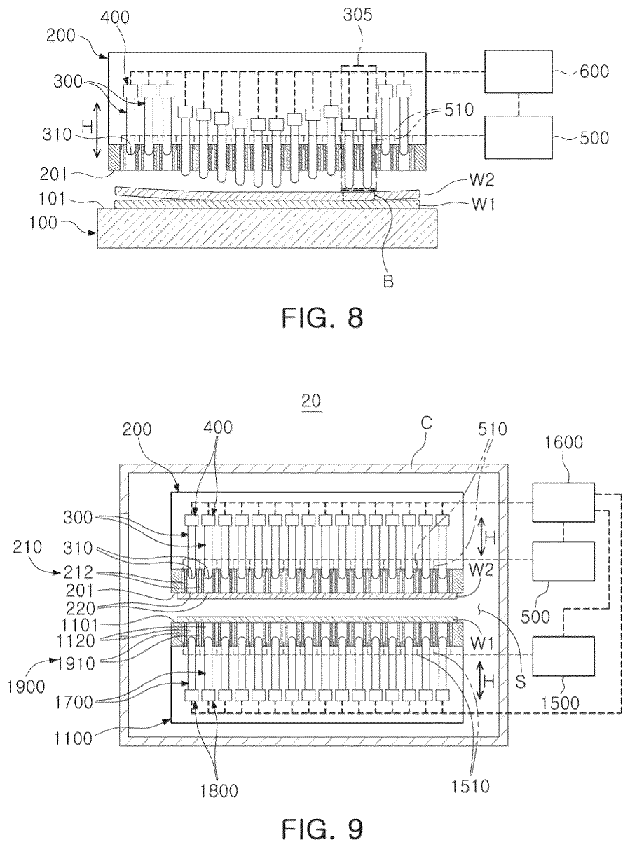

FIG. 2 is an exemplary diagram illustrating a wafer bonding apparatus according to one or more embodiments. FIG. 3 is a top view illustrating a second chuck, taken along line A-A of FIG. 2. FIG. 4 is an exemplary diagram illustrating a first position state of bonding pin members in a second chuck of a wafer bonding apparatus according to one or more embodiments. FIG. 5 is an exemplary diagram illustrating a second position state of bonding pin members in a second chuck of a wafer bonding apparatus according to one or more embodiments. FIG. 6 is an exemplary diagram illustrating a third position state of bonding pin members in a second chuck of a wafer bonding apparatus according to one or more embodiments. FIG. 7 is an exemplary diagram illustrating a fourth position state of bonding pin members in a second chuck of a wafer bonding apparatus according to one or more embodiments. FIG. 8 is an exemplary diagram illustrating a fifth position state of bonding pin members in a second chuck of a wafer bonding apparatus according to one or more embodiments.

Referring to FIG. 2, a wafer bonding apparatus 10 according to one or more embodiments may include a chamber portion C, a first chuck 100 configured to support a first wafer W1, a second chuck 200 configured to support a second wafer W2, a plurality of bonding pin members 300 disposed in the second chuck 200, and a plurality of drivers 400 connected to the plurality of bonding pin members 300, respectively.

The chamber portion C may include a processing space S in which the first chuck 100 and the second chuck 200 are disposed. The first wafer W1 and the second wafer W2 may be bonded in the processing space S of the chamber unit C, as described below. Various layers, such as an insulating layer including a silicon carbon nitride (SiCN) layer and a tetraethyl orthosilicate (TEOS) layer, a pattern layer and the like, may be formed on the first wafer W1 and the second wafer W2.

The first chuck 100 may be disposed in a lower region of the processing space S of the chamber portion C, and may have a first surface 101 on which the first wafer W1 is disposed. The first surface 101 of the first chuck 100 may in a flat shape, and the first wafer W1 may be supported on the first surface 101 of the first chuck 100 in a flat shape. However, embodiments are not limited thereto, and the first surface 101 of the first chuck 100 may have, for example, a convex shape, or may have a deformable shape using physical pressure from a pressing means such as air pressure, a pin and the like. The first wafer W1 may be suctioned and disposed on the first surface 101 of the first chuck 100 using various suction methods. In one or more embodiments, the first chuck 100 may be configured as a vacuum chuck, and vacuum may be provided to the first surface 101 of the first chuck 100 to suction the first wafer W1 on the first surface 101. However, embodiments are not limited thereto. As long as the first wafer W1 can be suctioned on the first surface 101, one or more embodiments may be implemented in various suction methods such as an electrostatic chuck.

The second chuck 200 may be disposed in an upper region of the processing space S of the chamber part C, and may include a second surface 201 facing the first surface 101 of the first chuck 100 and configured to suction the second wafer W2. In one or more embodiments, the second chuck 200 may be configured as a vacuum chuck, and may provide vacuum to the second surface 201 of the second chuck 200 to suction the second wafer W2 on the second surface 201. The second chuck 200 may be configured to be movable along a first direction H, perpendicular to the second surface 201, to bond the first wafer W1 and the second wafer W2.

The plurality of bonding pin members 300 may be disposed on the second chuck 200, arranged in a direction parallel to the second surface 201 of the second chuck 200, and individually operable. The plurality of bonding pin members 300 may be mounted on respective through holes 220 of the second chuck 200, and may be individually operated by a plurality of drivers 400, as described below. The plurality of bonding pin members 300 may press the second wafer W2 on a region basis when bonding the first wafer W1 and the second wafer W2. Accordingly, when bonding the first wafer W1 and the second wafer W2, the plurality of bonding pin members 300 corresponding to a center portion of the second wafer W2 may press the center portion of the second wafer W2, thereby more effectively preventing inflection points from occurring during the bonding process. In one or more embodiments, as shown in FIGS. 2 and 3, the plurality of bonding pin members 300 may be arranged across and to face the second surface 201 of the second wafer W2. The plurality of bonding pin members 300 may be arranged in the same size over the entire second surface 201 of the second wafer W2. In addition, in one or more embodiments, the plurality of bonding pin members 300 may be arranged at equal intervals from each other across the second surface 201 of the second wafer W2. However, the plurality of bonding pin members is not limited to this arrangement, and may be arranged in a variety of arrangement forms, such as being arranged in a method of forming a plurality of ring-shaped elements spaced radially around and adjacent to a center of the second wafer W2. Accordingly, pressure may be applied to a required region of the second wafer W2 as needed through the plurality of bonding pin members 300, thereby minimizing occurrence of inflection points of the second wafer W2 and enhancing bonding accuracy of the first wafer W1 and the second wafer W2, when bonding the first wafer W1 and the second wafer W2.

The plurality of drivers 400 may be connected to the plurality of bonding pin members 300, respectively, and may move the respective bonding pins member 300 in the first direction H, perpendicular to the second surface 201 of the second wafer W2. The plurality of drivers 400 may move the plurality of bonding pin members 300 using various driving methods. In one or more embodiments, the plurality of drivers 400 may each include an actuator connected to an upper part of the respective bonding pin member 300 to hold the respective bonding pin member 300, a motor connected to the actuator, etc. As the holding member move up and down in the first direction H by the motor, the plurality of bonding pin members 300 may be moved in the first direction H. The actuator may be implemented as various types of holding member, such as cylinders, screw nut power transmission mechanisms and the like, as long as the actuator is capable of moving the bonding pin member 300 in the first direction H. For each bonding pin member 300, a position in the first direction and pressing force on the second wafer W2 may be adjusted by the diver 400, when bonding the first wafer W1 and the second wafer W2. The wafer bonding apparatus 10 may include a controller 600 configured to control operations of each driver 400. The controller 600 may control the operations of each driver 400 according to control signals, so that the respective bonding pin member 300 may be moved by a set distance and press the second wafer W2 at a pressure set on a region basis. Accordingly, when bonding the first wafer W1 and the second wafer W2, the plurality of bonding pin members 300 may individually press the second wafer W2 or release pressures thereof on a region basis.

The second chuck 200 may include a plurality of vacuum regions 210 disposed adjacent to the respective bonding pin members 300. The plurality of vacuum regions 210 may be connected to the vacuum generator 500, and the vacuum generator 500 may provide vacuum to the required vacuum regions of the plurality of vacuum regions 210, thereby vacuum suctioning the required regions of the second wafer W2. In one or more embodiments, the vacuum regions 210 may be disposed around and adjacent to the respective bonding pin members 300. The vacuum regions 210 may be arranged around and adjacent to the respective bonding pin members 300 in various shapes, such as, for example, a ring-shape, an arc shape, a slit shape, a circular shape and the like. In one or more embodiments, a plurality of vacuum openings 212 may be spaced apart from each other in the vacuum regions 210 around and adjacent to the corresponding bonding pin members 300. One vacuum opening 212 may be disposed between the two bonding pin members 300 adjacent to each other. These plurality of vacuum regions 210 may be configured to individually adjust vacuum pressures. The vacuum openings 212 of each vacuum region 210 may be partitioned from each other and connected to independent vacuum connection lines 510, so that the vacuum pressures thereof may be adjusted individually. The vacuum opening 212 disposed around and adjacent to each bonding pin member 300 and the corresponding bonding pin member 300 may be configured to operate simultaneously.

However, embodiments are not limited thereto, and the vacuum regions may be arranged in various forms around and adjacent to the respective bonding pin members. For example, the vacuum regions may be in a ring-shaped form integrally connected around and adjacent to the circumference of each bonding pin member. The vacuum regions may include a plurality of pieces, such as a plurality of arc-shaped or slit-shaped pieces spaced apart from each other around and adjacent to the circumference of each bonding pin member.

In the process of bonding the first wafer W1 and the second wafer W2, a shape deformation in the center portion of the second wafer W2 may be greater than a shape deformation in the edge portion. Accordingly, the plurality of bonding pin members 300 positioned in the central region among the plurality of bonding pin members 300 may be moved in the first direction H to form tip portions 310 of the bonding pin members facing the second wafer W2 to have a convex shape, thereby minimizing the occurrence of an inflection point on the second wafer W2 when pressing the center portion of the second wafer W2. In addition, bonding may be performed at an appropriate timing over the entire area of the second wafer W2 through the vacuum region 210 disposed around and adjacent to each bonding pin member 300, so that the bonding timing may be more finely adjusted for each region of the first wafer W1 and the second wafer W2, and bonding accuracy of the first wafer W1 and the second wafer W2 may be further improved. Furthermore, deformation in the subsequent processes after the bonding of the first wafer W1 and the second wafer W2 is completed may be minimized, and in particular, an overlay distortion phenomenon may be improved by reducing an occurrence of overlay finger prints an overlay process caused by to the bonding process.

In one or more embodiments, during or after the bonding of the first wafer W1 and the second wafer W2, when a flexed portion occurs in the second wafer W2, the flexed portion of the second wafer W2 may be measured with a measuring apparatus such as a three-dimensional (3D) sensor for 3-dimensionally sensing a physical change in the entire area of the second wafer W2. The flexed portion of the second wafer W2 may be corrected by adjusting a pressing force of the bonding pin members 300 based on data measured by the measuring apparatus, and a bonding shape of the first wafer W1 and the second wafer W2 may be controlled. The 3D sensor is an example of the measuring device, as described above, but embodiments are not limited thereto, and the measuring device may be implemented as any apparatus that can measure the shape of the entire region of the second wafer W2 in various forms.

Hereinafter, a method of pressing the second wafer W2 by adjusting the plurality of bonding pin members 300 in various position states during the bonding of the first wafer W1 and the second wafer W2 will be described.

As illustrated in FIG. 4, the plurality of bonding pin members 300 positioned in the central region among the plurality of bonding pin members 300 may be moved in the first direction H to form tip portions 310 of the bonding pin members facing the second wafer W2 to have a convex shape, and not to provide vacuum to the vacuum regions 210 disposed around and adjacent to the plurality of respective bonding pin members 301 positioned in the center portion, thereby minimizing the occurrence of an inflection point on the second wafer W2 when pressing the center portion of the second wafer W2. At this time, the plurality of bonding pin members 302 positioned in the edge portion outside the center portion of the second wafer W2 may be maintained in their original positions, the plurality of vacuum regions 210 disposed around and adjacent to the plurality of respective bonding pin members 302 positioned in the edge portion may provide vacuum to suction and support the edge portion of the second wafer W2. Accordingly, by not providing vacuum to the plurality of vacuum region 210 disposed around and adjacent to the plurality of respective bonding pin members 302 positioned in the edge portion of the second wafer W2 after pressing the center portion of the second wafer W2 and bonding the center portion of the first wafer W1 therewith, it is possible to develop the bonding of the first wafer W1 and the second wafer W2 from the center portion to the edge portion.

In one or more embodiments, as illustrated in FIG. 5, among the plurality of bonding pin members 301 positioned in the central region of the second wafer W2 in the position shown in FIG. 4, the plurality of bonding pin members 301 positioned closest to at the center portion may not further protrude from the bonding pin members disposed therearound, and move toward the second surface 201 of the second chuck 200 to be in an inwardly concave shape.

In one or more embodiments, as shown in FIG. 6, among the plurality of bonding pin members 301 positioned in the central region of the second wafer W2 in the position shown in FIG. 4, the plurality of bonding pin members 301 positioned closest to the center portion may not further protrude from the bonding pin members disposed therearound, and move toward the second surface 201 of the second chuck 200 to be in an inwardly concave shape, and the tip portions 310 of the bonding pin members 300 may have an overall gently W-shaped curved surface.

In one or more embodiments, as shown in FIG. 7, the plurality of bonding pin members 300 may move such that the bonding pin members 300 positioned in the edge portion further protrude toward the second wafer W2 than the bonding pin members 300 positioned in the center portion, and the tip portions 310 of the bonding pin members 300 may have an overall concave curved shape.

In one or more embodiments, as shown in FIG. 8, the bonding pin members 305 corresponding to a region B where an inflection point occurs in the second wafer W2 among the plurality of bonding pin members 300 may be moved. By applying a customized pressing force to the corresponding region of the second wafer W2 to adjust a shape thereof, a bonding alignment may be corrected at a high level.

When bonding the first wafer W1 and the second wafer W2, the plurality of bonding pin members 300 may be adjusted to be in positions having various forms, in addition to adjusting the plurality of bonding pin members 300 in the positions having the forms described above.

In the above description, embodiments of the structures of the wafer bonding apparatus 10, in which the first wafer W1 in a flat shape are supported on the first surface 101 of the first chuck 100, have been described with reference to FIGS. 2 to 8. However, embodiments are not limited thereto, and separate pin members movable in the first direction H may be disposed on the first surface 101 of the first chuck 100, so that a structure, in which the first wafer W1 may be supported in a curved shape, may be applied, as will be described below with reference to FIG. 9.

Referring to FIG. 9, a wafer bonding apparatus 20 may include a chamber portion C, a first chuck 1100 configured to support the first wafer W1, a second chuck 200 configured to support the second wafer W2, a plurality of bonding pin members 300 disposed on the second chuck 200 and a plurality of drivers 400 connected to the plurality of bonding pin members 300.

In this embodiment, except for the structure in which a plurality of first pin members 1700, a plurality of first chuck bonding pin member drivers 1800 and a plurality of first chuck vacuum region 1900 are disposed, the chamber portion C, the second chuck 200, the bonding pin members 300, and the driving portion of the embodiments described with reference to FIGS. 2 to 8 may be similarly applied to the chamber portion C, the second chuck 200, the bonding pin members 300, and the driving portion of the present embodiment. Accordingly, redundant description thereof will be omitted.

As illustrated in FIG. 9, the wafer bonding apparatus 20 may include the plurality of first chuck bonding pin members 1700 disposed on the first chuck 1100, the plurality of first chuck bonding pin member drivers 1800 connected to the plurality of first chuck bonding pin members 1700 and a plurality of first chuck vacuum regions 1900 disposed on the first chuck 1100 and configured to vacuum suction the first wafer W1.

The first chuck 1100 may be disposed in a lower area of a processing space S of the chamber portion C, and may have a first surface 1101 on which the first wafer W1 is disposed. The first surface 1101 of the first chuck 1100 may have a flat shape.

The plurality of first chuck bonding pin members 1700 may be arranged in a direction parallel to the first surface 1101 of the first chuck 1100, and individually operable. The plurality of first chuck bonding pin members 1700 may be mounted on respective through holes 1120 of the first chuck 1100, and may be individually operated by a plurality of first chuck bonding pin member drivers 1800, as described below. The plurality of first chuck bonding pin members 1700 may be disposed on the first chuck 1100 corresponding to the respective bonding pin members 300 disposed on the second chunk 200. The plurality of first chuck bonding pin members 1700 may press the first wafer W1 on a region basis when bonding the first wafer W1 and the second wafer W2. Accordingly, it is possible to ensure improved bonding of the first wafer W1 and the second wafer W2 by the plurality of the first chuck bonding pin members 1700 disposed on the first chuck 1100 and the plurality of the bonding pin members 300 disposed on the second chuck 200, and to more effectively prevent the occurrence of inflection points due to pressure on the first wafer W1 and the second wafer W2. In one or more embodiments, the plurality of first chuck bonding pin members 1700 may be arranged across and to face the first surface 1101 of the first wafer W1. The plurality of first chuck bonding pin members 1700 may be arranged in the same size and spacing over the entire first surface 1101 of the first wafer W1. Accordingly, pressure may be applied to a required region of the first wafer W1 as needed through the plurality of first chuck bonding pin members 1700, thereby enhancing bonding accuracy of the first wafer W1 and the second wafer W2.

The plurality of first chuck bonding pin member drivers 1800 may be connected to the plurality of first chuck bonding pin members 1700, respectively, and may move the respective first chuck bonding pins member 1700 in the first direction H. The plurality of first chuck bonding pin member drivers 1800 may move the plurality of first chuck bonding pin members 1700 using various driving methods. In one or more embodiments, the plurality of first chuck bonding pin member drivers 1800 may each include an actuator connected to an upper part of the respective first chuck bonding pin member 1700 to hold the respective first chuck bonding pin member 1700, a motor connected to the actuator, etc. As the holding member move up and down in the first direction H by the motor, the plurality of first chuck bonding pin members 1700 may be moved in the first direction H. The actuator may be implemented as various types of holding member capable of moving the first chuck bonding pin member 1700 in the first direction H. For each first chuck bonding pin member 1700, a position in the first direction and pressing force on the first wafer W1 may be adjusted by the first chuck bonding pin diver 400, when bonding the first wafer W1 and the second wafer W2. In one or more embodiments, the first chuck bonding pin member drivers 1800 may have the same structure as the drivers 400 that move the plurality of bonding pin members 300 disposed on the second chuck 200. A controller 1600 may control operations of each driver 400, and also control operations of each first chuck bonding pin member driver 1800. The controller 1600 may control the operations of each first chuck bonding pin member driver 1800 according to control signals, so that the respective first chuck bonding pin member 1700 may be moved by a set distance and press the first wafer W1 at a pressure set on a region basis. Accordingly, when bonding the first wafer W1 and the second wafer W2, the plurality of first chuck bonding pin members 1700 may individually press the first wafer W1 or release pressures thereof on a region basis.

According to one or more embodiments, the controller 1600 may control the first chuck bonding pin member driver 1800 and the driver 300 such that the first chuck bonding pin members 1700 disposed on the first chuck 1100 and the bonding pin members 300 disposed on the second chuck 200 are symmetrical to each other.

The first chuck vacuum regions 1900 may have various forms that are capable of performing vacuum suctioning of the first wafer W1. In one or more embodiments, the first chuck vacuum regions 1900 may be disposed around and adjacent to the respective first chuck bonding pin members 1700 in the same shape as the vacuum regions 210 formed in the second chuck 200, and may include a plurality of first chuck vacuum openings 1910 whose vacuum pressures can be individually adjusted. The plurality of first chuck vacuum openings 1910 may be connected to a vacuum generator 1500 through respective vacuum connection lines 1510. Accordingly, bonding may be performed at an appropriate timing over the entire area of the second wafer W2 through the first vacuum region 1900 disposed around and adjacent to each first chuck bonding pin member 1700, so that the bonding timing may be finely adjusted for each region of the first wafer W1 and the second wafer W2, and bonding accuracy of the first wafer W1 and the second wafer W2 may be further improved. Furthermore, deformation in the subsequent process after the bonding of the first wafer W1 and the second wafer W2 is completed may be minimized, and in particular, an overlay distortion phenomenon may be improved by reducing an occurrence of overlay finger prints an overlay process caused by to the bonding process.

One or more embodiments may provide a wafer bonding apparatus that may improve bonding accuracy by applying pressure to a wafer on a region basis.

Additionally, one or more embodiments may provide a wafer bonding apparatus that may improve overlay distortion in subsequent processes after bonding.

While embodiments have been shown and described above, it will be apparent to those skilled in the art that modifications and variations could be made without departing from the scope of the present inventive concept as defined by the appended claims and their equivalents.

What is claimed is:

1. A wafer bonding apparatus, comprising:
a first chuck configured to suction a first wafer on a first surface of the first chuck;
a second chuck configured to suction a second wafer on a second surface of the second wafer that faces the first surface of the first chuck;
a plurality of bonding pin members in the second chuck in a direction parallel to the second surface of the second chuck, the plurality of bonding pin members being configured to be individually operable; and
a plurality of drivers connected to the plurality of bonding pin members, respectively, the plurality of drivers being configured to move the connected plurality of bonding pin members, respectively, in a first direction perpendicular to the second surface of the second chuck,
wherein the second chuck comprises a plurality of vacuum regions adjacent to the plurality of bonding pin members, respectively.

2. The wafer bonding apparatus of claim 1, wherein the plurality of bonding pin members face the second surface of the second chuck.

3. The wafer bonding apparatus of claim 2, wherein the plurality of bonding pin members are disposed at equal intervals and face the second surface of the second chuck.

4. The wafer bonding apparatus of claim 1, wherein, based on bonding the first wafer and the second wafer, a position of each bonding pin of the plurality of bonding pin members in the first direction and a pressing force of each bonding pin of the plurality of bonding pin members on the second wafer are adjusted by each driver of the plurality of drivers.

5. The wafer bonding apparatus of claim 1, wherein each of the plurality of vacuum regions is adjacent to each bonding pin member of the plurality of bonding pin members.

6. The wafer bonding apparatus of claim 1, wherein a plurality of vacuum openings are spaced apart from each other in each vacuum region of the plurality of vacuum regions adjacent to each bonding pin member of the plurality of bonding pin members.

7. The wafer bonding apparatus of claim 6, wherein at least one vacuum opening of the plurality of vacuum openings is between the plurality of bonding pin members adjacent to each other.

8. The wafer bonding apparatus of claim 1, wherein vacuum pressures of the plurality of vacuum regions are configured to be individually adjusted.

9. A wafer bonding apparatus, comprising:
a first chuck configured to suction a first wafer on a first surface of the first chuck;
a second chuck configured to suction a second wafer on a second surface of the second chuck that faces the first surface;
a plurality of bonding pin members in the second chuck and in a direction parallel to the second surface, the plurality of bonding pin members being configured to be individually operable; and
a plurality of drivers connected to the plurality of bonding pin members, respectively, the plurality of drivers being configured to move the connected plurality of bonding pin members, respectively, in a first direction perpendicular to the second surface of the second chuck,
wherein the second chuck comprises a plurality of vacuum openings adjacent to the plurality of bonding pin members, respectively, and vacuum pressures of the plurality of vacuum openings being configured to be individually adjustable.

10. The wafer bonding apparatus of claim 9, wherein each bonding pin of the plurality of bonding pin members and each vacuum opening of the plurality of vacuum openings adjacent to each other are configured to operate simultaneously.

11. The wafer bonding apparatus of claim 10, wherein at least one vacuum opening of the plurality of vacuum openings is between the plurality of bonding pin members adjacent to each other.

12. The wafer bonding apparatus of claim 9, wherein the plurality of bonding pin members face the second surface of the second chuck.

13. The wafer bonding apparatus of claim 9, wherein the plurality of bonding pin members are disposed at equal intervals, have equal sizes, and face the second surface of the second chuck.

14. The wafer bonding apparatus of claim 9, wherein, based on bonding the first wafer and the second wafer, a position of each bonding pin of the plurality of bonding pin members in the first direction and a pressing force of each bonding pin of the plurality of bonding pin members on the second wafer are adjusted by each driver of the plurality of drivers, respectively.

15. The wafer bonding apparatus of claim 9, further comprising:
a plurality of first chuck bonding pin members in the first chuck in a direction parallel to the first surface, the plurality of first chuck bonding pin members being configured to be individually operable; and
a plurality of first chuck bonding pin member drivers connected to the plurality of first chuck bonding pin members, respectively, the plurality of first chuck bonding pin member drivers being configured to move the plurality of first chuck bonding pin members, respectively, in the first direction.

16. The wafer bonding apparatus of claim 15, wherein the plurality of first chuck bonding pin members are on the first chuck to correspond to the plurality of bonding pin members, respectively, on the second chuck.

17. The wafer bonding apparatus of claim 15, wherein the plurality of first chuck bonding pin members face the second surface.

18. The wafer bonding apparatus of claim 15, wherein the first chuck comprises a plurality of first chuck vacuum regions configured to vacuum suction the first wafer.

19. The wafer bonding apparatus of claim 15, wherein the first chuck comprises a plurality of first chuck vacuum openings adjacent to the plurality of first chuck bonding members, respectively, and vacuum pressures of the plurality of first chuck vacuum openings are configured to be individually adjustable.

20. A wafer boding apparatus, comprising:
a chamber portion comprising a processing space;
a first chuck in a first region of the processing space, the first chuck being configured to vacuum-suction a first wafer on a first surface of the first chuck;
a second chuck configured to vacuum-suction a second wafer on a second surface of the second chuck facing the first surface;
a plurality of bonding pin members in the second chuck in a direction parallel to the second surface, the plurality of bonding pin members being configured to be individually operable; and
a plurality of drivers connected to the plurality of bonding pin members, respectively, the plurality of drivers being configured to move the plurality of bonding pin members, respectively, in a first direction perpendicular to the second surface of the second chuck,
wherein the second chuck comprises a plurality of vacuum regions adjacent to the plurality of bonding pin members, respectively, vacuum pressures of the plurality of vacuum regions being configured to be individually adjusted, and a plurality of vacuum openings being spaced apart from each other in each vacuum region of the plurality of vacuum regions adjacent to the plurality of bonding pin members, respectively.
